(19) United States
(12) Patent Application Publication
(10) Pub. No.: US 2023/0082145 A1
(43) Pub. Date: Mar. 16, 2023

(54) COPPER-BASED ALLOY SPUTTERING TARGET AND METHOD FOR MAKING THE SAME

(71) Applicant: SOLAR APPLIED MATERIALS TECHNOLOGY CORP., Tainan City (TW)

(72) Inventors: Shou-Hsien LIN, Tainan City (TW); Tsung-Hsien HSIEH, Tainan City (TW); Yu-An YE, Tainan City (TW)

(21) Appl. No.: 17/891,883

(22) Filed: Aug. 19, 2022

(30) Foreign Application Priority Data
Aug. 25, 2021 (TW) 110131485

(51) Int. Cl. C23C 14/34; C22C 9/05

(52) U.S. Cl. CPC C23C 14/3414; C22C 9/05

(57) ABSTRACT

A copper-based alloy sputtering target includes copper and a metal element selected from manganese, chromium, cobalt, aluminum, tin, titanium, and combinations thereof. Based on a total weight of the copper-based alloy sputtering target, copper is present in an amount of not less than 98 wt %, and the metal element is present in an amount ranging from 0.3 wt % to 2.0 wt %. The copper-based alloy sputtering target has an average value of Kernel Average Misorientation of not greater than 2° as determined by Electron Backscatter Diffraction, and an average value of Vickers hardness on a sputtering surface that ranges from 90 Hv to 120 Hv. A method for making the copper-based alloy sputtering target is also disclosed.

### CROSS-REFERENCE TO RELATED APPLICATION

This application claims priority of Taiwanese Invention Patent Application No. 110131485, filed on Aug. 25, 2021.

### FIELD

The present disclosure relates to a sputtering target, and more particularly to a copper-based alloy sputtering target. The present disclosure also relates to a method for making the copper alloy sputtering target.

### BACKGROUND

Conventional copper alloy sputtering target for use in semiconductor industry might be categorized into two types. One type is a copper alloy ingot, with a back surface thereof being bonded to a backing plate, whereas the other type is a monolithic copper alloy sputtering target. The target utilization rate of the monolithic copper alloy sputtering target might be greater than 40%, which is higher than that of the copper alloy sputtering target with the backing plate bonded thereto (generally ranging from 30% to 40%). In addition, the monolithic copper alloy sputtering target might reduce electrical conductivity problem or thermal conductivity problem caused by difference in material properties and existence of interface between the backing plate and the copper alloy ingot, and thus, in recent years, it is favored by the semiconductor-related industries. However, since the monolithic copper alloy sputtering target would be deformed due to decrease thickness thereof with increased sputtering time period, such copper alloy sputtering targets should have sufficient mechanical strength. For the aforesaid two types of the copper alloy sputtering target, conventional techniques to improve the mechanical strength of the copper alloy sputtering target (i.e., hardening) include cold forming and grain refinement, etc.

Taiwanese Invention Patent No. TW 1560290 B discloses a method for making a high-purity copper sputtering target as follows. Copper having a purity of 6N was melted in a carbon crucible under a high vacuum atmosphere and then the molten copper was casted into a carbon mold to form an ingot. Subsequently, the produced ingot was subjected to warm forging at 400° C., and then performing in sequence, a cold rolling process at a cold working ratio ranging from 78% to 82%, a heating treatment at a temperature ranging from 300° C. to 350° C. for 1 hour, and a cold forging process at peripheral regions thereof under a working ratio ranging from 30% to 50%. Then, the obtained product was machined and processed into the target which has an erosion part and a flange part that surrounds the erosion part and that corresponds to outer periphery of the target.

By enhancing a Vickers hardness of the flange part to achieve a range of 90 Hv to 100 Hv, the high-purity copper sputtering target disclosed by TW 1560290 B, even if the Vickers hardness of the erosion part only ranges from 61 Hv to 67 Hv, can cause the amount of warpage to be in a range of 0.8 mm to 1.6 mm. However, the hardness of the erosion part is still insufficient, and thus deformation of the target might easily occur at middle stages and later stages of sputtering process.

Taiwanese Invention Patent No. TW 1539019 B discloses a high-purity copper-manganese-alloy sputtering target, which was made as follows. First, high-purity copper having a purity of 6 N was melted in a carbon crucible under a high vacuum atmosphere, and then high-purity manganese having a purity of 5 N was charged into the molten copper, in which the amount of manganese was adjusted to range from 0.05 wt % to 20 wt %. After melting at 1200° C. for 20 minutes, the molten copper-manganese alloy was cast in a water-cooled copper mold under a high vacuum atmosphere to obtain an ingot. Thereafter, the surface layer of the ingot was removed to obtain a size ranging from φ160×60t to φ60×190t, followed by hot forging into φ200. Subsequently, cold-rolling and then hot-rolling at a temperature ranging from 800° C. to 900° C. were performed to obtain a size ranging from φ380×10t to φ700×10t. After a heating treatment at 600° C. for 1 hour, a quenching process was performed to obtain a target material. Finally, the target material was machined to obtain the copper-manganese-alloy sputtering target having a diameter of 430 mm and a thickness of 7 mm, which was further connected to a copper alloy backing plate by diffusion bonding so as to obtain a sputtering target assembly.

Although the mechanical strength of the copper-manganese alloy sputtering target of TW 1539019 B is improved by a series of procedures such as hot forging, cold rolling, hot rolling, heat treatment and quenching after casting of the ingot, the sputtering target assembly formed by diffusion bonding of the copper-manganese-alloy sputtering target to the backing plate made of heterogeneous materials not only has a low utilization rate, but also is prone to have electrical/thermal conduction problem.

Therefore, under the premise of increasing the utilization rate of a sputtering target, there is still a need for those skilled in the art to develop an improved copper-based alloy sputtering target which can reduce warpage of the target in middle stage (before later stage) of the sputtering process and decrease the amount of undesired contaminant particles (i.e., dust adhering to wafer substrate) generated during the sputtering process.

### SUMMARY

Therefore, an object of the present disclosure is to provide a copper-based alloy sputtering target and a method for making the same which can alleviate at least one of the drawbacks of the prior art.

According to one aspect of the present disclosure, the copper-based alloy sputtering target includes copper and a metal element selected from the group consisting of manganese, chromium, cobalt, aluminum, tin, titanium, and combinations thereof. Based on a total weight of the copper-based alloy sputtering target, copper is present in an amount of not less than 98 wt %, and the metal element is present in an amount ranging from 0.3 wt % to 2.0 wt %. The copper alloy sputtering target has an average value of Kernel Average Misorientation (KAM) of not greater than 2°, as determined by Electron Backscatter Diffraction (EBSD), and an average value of Vickers hardness on a sputtering surface that ranges from 90 Hv to 120 Hv.

According to another aspect of the present disclosure, the method for making the aforesaid copper-based alloy sputtering target includes the steps of:

(a) melting copper and a metal element selected from the group consisting of manganese, chromium, cobalt, aluminum, tin, titanium, and combinations thereof to form a molten copper-based alloy in which based on a total weight of the molten copper-based alloy, copper is present in an amount of not less than 98 wt %, and the metal element is present in an amount ranging from 0.3 wt % to 2.0 wt %;

(b) casting the molten copper-based alloy in a mold to form a copper-based alloy ingot;

(c) subjecting the copper-based alloy ingot to a hot forging process at a forging ratio of greater than 40% under a temperature ranging from 600° C. to 1000° C.;

(d) subjecting the forged product obtained in step (c) to a heating treatment at a temperature ranging from 400° C. to 700° C. for a time period ranging from 1 hour to 3 hours;

(e) subjecting the heat-treated product obtained in step (d) to a cold rolling process at a cold rolling rate ranging from 40% to 75%;

(f) subjecting the cold-rolled product obtained in step (e) to a recrystallization heating treatment at a temperature ranging from 450° C. to 700° C. for a time period ranging from 1 hour to 3 hours; and

(g) subjecting the recrystallized product obtained in step (f) to a cold forming process at a cold working rate of not greater than 50% under a room temperature, so as to obtain the copper-based alloy sputtering target.

### BRIEF DESCRIPTION OF THE DRAWINGS

Other features and advantages of the present disclosure will become apparent in the following detailed description of the embodiments with reference to the accompanying drawings, of which:

FIG. 1 is a schematic top view illustrating two positions of an embodiment of a copper-based alloy sputtering target according to the present disclosure from which test samples are respectively prepared for determination of Kernel Average Misorientation (KAM) by Electron Backscatter Diffraction (EBSD);

FIG. 2 is a schematic front view illustrating 31 measurement points of each of the test samples taken from the two positions of the embodiment as shown in FIG. 1 for determination of KAM by EBSD; and

FIG. 3 is a schematic top view illustrating three positions in the embodiment of the copper-based alloy sputtering target according to the present disclosure from which test samples are respectively prepared for determination of Vickers hardness.

### DETAILED DESCRIPTION

It is to be understood that, if any prior art publication is referred to herein, such reference does not constitute an admission that the publication forms a part of the common general knowledge in the art, in Taiwan or any other country.

For the purpose of this specification, it will be clearly understood that the word “comprising” means “including but not limited to”, and that the word “comprises” has a corresponding meaning.

Unless otherwise defined, all technical and scientific terms used herein have the meaning commonly understood by a person skilled in the art to which this disclosure belongs. One skilled in the art will recognize many methods and materials similar or equivalent to those described herein, which could be used in the practice of this disclosure. Indeed, this disclosure is in no way limited to the methods and materials described.

An embodiment of a copper-based alloy sputtering target of the present disclosure includes copper and a metal element selected from the group consisting of manganese, chromium, cobalt, aluminum, tin, titanium, and combinations thereof. Based on a total weight of the copper-based alloy sputtering target, copper is present in an amount of not less than 98 wt %, and the metal element is present in an amount ranging from 0.3 wt % to 2.0 wt %. The copper-based alloy sputtering target has an average value of Kernel Average Misorientation (KAM) of not greater than 2°, as determined by Electron Backscatter Diffraction (EBSD), and an average value of Vickers hardness on a sputtering surface that is not less than 90 Hv. In this embodiment, the metal element is manganese.

It should be noted that when performing a sputtering process on a sputtering target, sputtering sources usually employ magnetrons that utilize strong electric and magnetic fields to confine charged plasma particles in a position close to a surface of the sputtering target, causing electrons, in the magnetic field, travel along helical paths around magnetic field lines to increase probability of ionization by collisions with gaseous neutral particles near the surface of the sputtering target, such that ionized cations thus generated will bombard the surface of the sputtering target to form a sputtering profile which is shown as a “racetrack erosion” on the surface of the sputtering target. Therefore, the aforesaid sputtering surface of the copper-based sputtering target refers to a region on the surface of the copper-based sputtering target which is bombarded by ions.

In certain embodiments, the copper-based alloy sputtering target has an average crystal grain size of not greater than 30 μm as determined according to ASTM E112. In certain embodiments, the average value of KAM of the copper-based alloy sputtering target ranges from 0.9° to 1.9°, as determined by EBSD. In certain embodiments, the average value of Vickers hardness on the sputtering surface ranges from 90 Hv to 120 Hv.

According to this disclosure, an embodiment of a method for making the copper-based alloy sputtering target as mentioned above includes the following steps (a) to (g).

In step (a), copper and the metal element (such as Mn) are melted to form a molten copper-based alloy in which based on a total weight of the molten copper-based alloy, copper is present in an amount of not less than 98 wt %, and the metal element is present in an amount ranging from 0.3 wt % to 2.0 wt %. In step (b), the molten copper-based alloy is casted in a mold to form a copper-based alloy ingot.

In step (c), the copper-based alloy ingot is subjected to a hot forging process at a forging ratio of greater than 40% under a temperature ranging from 600° C. to 1000° C. It should be noted that the hot forging process performed at the forging ratio of greater than 40% aims to allow the copper-based alloy ingot to undergo plastic deformation under a temperature higher than a recrystallization temperature while continuing recrystallization, thereby achieving crystal grain refinement. In certain embodiments, the forging ratio of the hot forging process ranges from 40% to 50%, so as to provide an optimized crystal grain refinement.

In step (d), the forged product obtained in step (c) is subjected to a heating treatment at a temperature ranging from 400° C. to 700° C. for a time period ranging from 1 hour to 3 hours. In certain embodiments, the temperature of the heating treatment ranges from 400° C. to 550° C.

In step (e), the heat-treated product obtained in step (d) is subjected to a cold rolling process at a cold rolling rate ranging from 40% to 75%. It should be noted that the cold rolling process performed at the cold rolling rate ranging from 40% to 75% aims to allow the heat-treated product to accumulate within an inner portion thereof, a residual stress generated by dislocation kink which is caused by the aforesaid plastic deformation, so as to increase a hardness of the heat-treated product. In order to achieve more sufficient and higher amount of the residual stress, in certain embodiments, the cold rolling rate of the cold rolling process ranges from 65% to 75%.

In step (f), the cold-rolled product obtained in step (e) is subjected to a recrystallization heating treatment at a temperature ranging from 450° C. to 700° C. for a time period ranging from 1 hour to 3 hours so as to obtain a recrystallized product. It should be noted that the recrystallization heating treatment which is performed after the cold rolling process mentioned in step (e) aims to allow the cold-rolled product to undergo an annealing process which includes a recovery stage and a recrystallization stage in sequence. To be specific, when a temperature for the recovery stage is reached, the residual stress in the inner portion of the cold-rolled product is released to allow dislocations to be rearranged into a polygonized structure, which forms a sub-grain structure in an inner portion of a normal crystal grain, and the rearranged dislocations become boundary regions of the sub-grain structure. When a temperature for the recrystallization stage is reached, new crystal grains nucleate at the boundary regions of the sub-grain structure to eliminate most of the dislocations, resulting in further refinement of the crystal grains of the thus obtained recrystallized product, and reduces strength and increases ductility of the recrystallized product.

In other words, step (f) is performed to reduce strain energy in the inner portion of the recrystallized product and to refine the crystal grains thereof.

In step (g), the recrystallized product obtained in step (f) is subjected to a cold forming process at a cold working rate of not greater than 50% under a room temperature, so as to obtain the copper-based alloy sputtering target. It should be noted that by performing step (c) to (f), in which the copper-based alloy ingot obtained in step (b) is subjected to a primary crystal grain refinement and work hardening and then to a secondary crystal grain refinement to reduce strain energy therein, the cold forming process which is performed at the cold working rate of not greater than 50% under the room temperature in step (g) aims to allow the recrystallized product that has gained initial strength after the secondary crystal grain refinement to be further work-hardened, so as to avoid accumulation of excessive strain energy in the thus obtained copper-based alloy sputtering target. Examples of the cold forming process include, but are not limited to, cold rolling, cold forging, cold extrusion, cold drawing, and combinations thereof.

The present disclosure will be further described by way of the following examples. However, it should be understood that the following examples are intended solely for the purpose of illustration and should not be construed as limiting the present disclosure in practice.

### EXAMPLES AND COMPARATIVE EXAMPLES

In the following methods of Examples 1 to 3 and Comparative Examples 1 to 3 for forming the copper-based alloy sputtering target, manganese was served as a metal element to be melted with copper, and the abovementioned steps (a) to (g) of the methods are performed under different conditions as summarized in Table 1 and described in details as follows.

### Example 1 (EX1)

First, copper having a purity of 6 N and manganese having a purity of greater than 5 N were melted in a graphite crucible by induction heating under a vacuum environment to form a molten copper-based alloy in which based on a total weight of the molten copper-based alloy, manganese is present in an amount of 0.3 wt %. Next, the molten copper-based alloy was casted into a plurality of water-cooled copper crucibles to form a plurality of copper-based alloy ingots, respectively. Thereafter, each of the copper-based alloy ingots were subjected to a hot forging process at a forging ratio of 47% under a temperature of 700° C. to obtain a forged product, which was then subjected to a heating treatment under a temperature of 550° C. for a time period of 1 hour to obtain a heat-treated product. Subsequently, the heat-treated product was subjected to a cold rolling process at a cold rolling rate of 73% to obtain a cold-rolled product, which was then subjected to a recrystallization heating treatment under a temperature of 450° C. for a time period of 1 hour to obtain a recrystallized product. After that, the recrystallized product was subjected to a cold forming process, i.e., the cold rolling process, at a cold working rate of less than 50% under a room temperature ranging from 25° C. to 27° C., followed by a machining process so as to obtain a copper-based alloy sputtering target.

### Example 2 (EX2)

The method of EX2 was similar in procedures to those conducted in EX1, except that, in EX2, manganese is present in an amount of 0.8 wt % based on the total weight of the molten copper-based alloy, the hot forging process was conducted at a forging ratio of 43% under 750° C., the heating treatment was conducted at 500° C. for 1 hour, the cold rolling process was conducted on the heat-treated product at a cold rolling rate of 65%, the recrystallization heating treatment was conducted at 550° C. for 3 hours, and the cold forming process (i.e., the cold rolling process) was conducted on the recrystallized product at a cold working rate of less than 45%.

### Example 3 (EX3)

The method of EX3 was similar in procedures to those conducted in EX1, except that, in EX3, manganese is present in an amount of 2.0 wt % based on the total weight of the molten copper-based alloy, the hot forging process was conducted at a forging ratio of 42% under 750° C., the heating treatment was conducted at 400° C. for 1 hour, the cold rolling process was conducted on the heat-treated product at a cold rolling rate of 68%, the recrystallization heating treatment was conducted at 700° C. for 1 hour, and the cold forming process (i.e., a cold forging process) was conducted on the recrystallized product at a cold working rate of less than 45%.

### Comparative Example 1 (CE1)

The method of CE1 was similar in procedures to those conducted in EX1, except that, in CE1, the hot forging process was conducted at a forging ratio of 67% under 850° C., the heating treatment was conducted at 600° C. for 1 hour, the cold rolling process was conducted on the heat-treated product at a cold rolling rate of 52%, the recrystallization heating treatment was conducted at 450° C. for 1 hour, and the cold forming process was not performed on the recrystallized product.

### Comparative Example 2 (CE2)

The method of CE2 was similar in procedures to those conducted in EX2, except that, in CE2, the copper-based alloy ingot was subjected to the hot forging process at a forging ratio of 58% under 800° C., the heating treatment was conducted at 350° C. for 1 hour, the cold rolling process was conducted on the heat-treated product at a cold rolling rate of 55%, the recrystallization heating treatment was conducted at 750° C. for 3 hours, and the cold forming process, i.e., the cold rolling process, was conducted on the recrystallized product at a cold working rate of 55%.

### Comparative Example 3 (CE3)

The method of CE3 was similar in procedures to those conducted in EX3, except that, in CE3, the copper-based alloy ingot was subjected to the hot forging process at a forging ratio of 60% under 900° C., the heating treatment was conducted at 350° C. for 1 hour, the cold rolling process was conducted on the heat-treated product at a cold rolling rate of 60%, the recrystallization heating treatment was conducted at 700° C. for 0.5 hours, and the cold forming process, i.e., the cold forging process, was conducted on the recrystallized product at a cold working rate of 70%.

For clarity, for each of the methods of EX1 to EX3 and CE1 to CE3, the amount of manganese melted with copper, and the conditions for performing the hot forging process, the heating treatment, the cold rolling process, the recrystallization heating treatment, and the cold forming process are summarized and shown in Table 1 below.

TABLE 1

| Method | | EX1 | EX2 | EX3 | CE1 | CE2 | CE3 |
|---|---|---|---|---|---|---|---|
| Metal element | Manganese | 0.3 | 0.8 | 2.0 | 0.3 | 0.8 | 2.0 |
| | (wt %) | | | | | | |
| Hot forging | Temperature | 700 | 750 | 750 | 850 | 800 | 900 |
| process | (° C.) | | | | | | |
| | Forging | 47 | 43 | 42 | 67 | 58 | 60 |
| | ratio (%) | | | | | | |
| Heating treatment | Temperature | 550 | 500 | 400 | 600 | 350 | 350 |
| | (° C.) | | | | | | |
| | Time period | 1 | 1 | 1 | 1 | 1 | 1 |
| | (hour) | | | | | | |
| Cold rolling | Cold | 73 | 65 | 68 | 52 | 55 | 60 |
| process | rolling | | | | | | |
| | rate (%) | | | | | | |
| Recrystallization | Temperature | 450 | 550 | 700 | 450 | 750 | 700 |
| heating treatment | (° C.) | | | | | | |
| | Time period | 1 | 3 | 1 | 1 | 3 | 0.5 |
| | (hour) | | | | | | |
| Cold forming | Type | Cold | Cold | Cold | — | Cold | Cold |
| process | | rolling | rolling | forging | | rolling | forging |
| | Cold | <50% | <45% | <45% | — | 55% | 70% |
| | working | | | | | | |
| | rate (%) | | | | | | |

“—“: not performed

Property Evaluations

Each of the copper-based alloy sputtering targets prepared by the aforesaid methods of EX1 to EX3 and CE1 to CE3 was subjected to property evaluations as described below.

### 1. Composition Analysis

A test sample having a dimension of 20 mm×20 mm was taken from a peripheral region of each of the copper-based alloy sputtering targets prepared in EX1 to EX3 and CE1 to CE3, and then subjected to composition analysis using inductively coupled plasma optical emission spectrometer (ICP-OES) (Manufacturer: PerkinElmer, Inc.; Model: Optima 5300 DV) so as to determine the amount of manganese thereof. The results are shown in Table 2 below.

### 2. Kernel Average Misorientation (KAM)

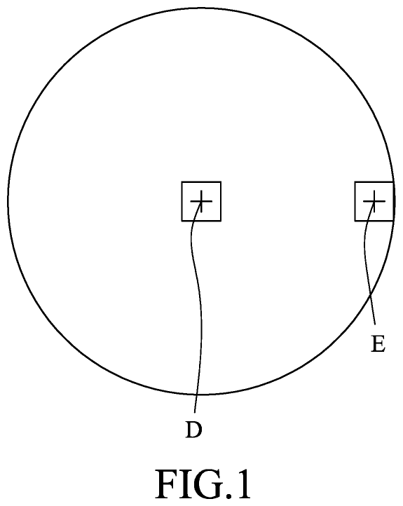

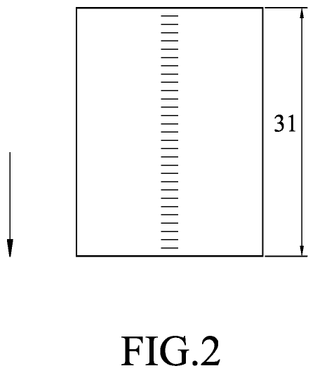

Electron Backscatter Diffraction (EBSD) data of each of the copper-based alloy sputtering targets prepared in EX1 to EX3 and CE1 to CE3 were collected using an EBSD detector (purchased from EDAX, Inc.), and then were analyzed using OIM Analysis™ (developed by EDAX, Inc.), so as to determine KAM value. To be specific, for each of the copper-based alloy sputtering targets, two test samples, each having a thickness of 30 mm, were respectively taken from a central region (D) and a peripheral region (E) thereof (see FIG. 1), and then EBSD data of each of the test samples were collected from 31 measurement points which are spaced apart from one other by a distance of 1 mm along a thickness direction of each test sample, i.e., from an upper surface to a lower surface thereof (see FIG. 2), under a magnification of 200×. For each test sample, the EBDS data collected from each of the 31 measurement points were analyzed using the OIM Analysis™ to obtain a corresponding one of KAM values, such that a total of 62 KAM values was obtained from the two samples of each of the copper-based alloy sputtering targets, and then was calculated and averaged to obtain an average KAM value for each of the copper-based alloy sputtering targets. The results are shown in Table 2 below.

It should be noted that since KAM may represent changes in local misorientation within crystal grains of a crystalline material, a KAM mapping image could show regions having increased density of crystal orientation defects so as to predict strain changes in the crystalline material, and the average KAM value is usually utilized to quantitatively determine the degree of plastic strain in the crystalline material. In other words, a higher KAM value indicates that the degree of plastic deformation and the density of crystal orientation defects are greater, and therefore the crystalline material is prone to have excessive strain energy accumulated therein.

### 3. Crystal Grain Size

The average crystal grain size of each of the copper-based alloy sputtering targets prepared in EX1 to EX3 and CE1 to CE3 was measured according to the procedures set forth in ASTM E112. The results are shown in Table 2 below.

### 4. Vickers Hardness

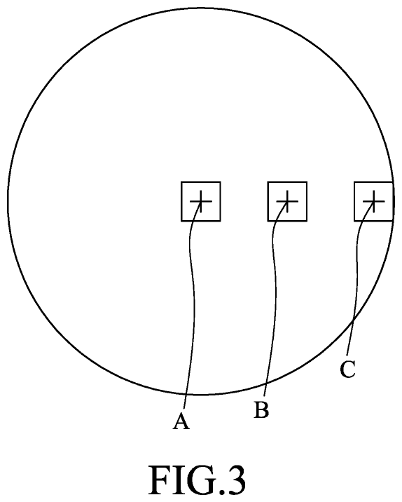

For each of the copper-based alloy sputtering targets prepared in EX1 to EX3 and CE1 to CE3, three test samples, each having a dimension of 10 mm×10 mm, were respectively taken from positions located at a center (A), a half radius (B), and a periphery (C) thereof (see FIG. 3), and then a sputtering surface of each of the test samples was polished to measure Vickers hardness thereof using a micro-hardness tester (Manufacturer: Shimadzu Corporation; Model no.: HMV-2), followed by calculation and averaging to obtain an average Vickers hardness value for each of the copper-based alloy sputtering targets. The results are shown in Table 2 below.

### 5. Sputtering Characteristic Test

Each of the copper-based alloy sputtering targets prepared in EX1 to EX3 and CE1 to CE3 was supplied with an output power ranging from 4 W/cm² to 8 W/cm², and subjected to a sputtering process under a working pressure ranging from 10 mTorr to 20 mTorr and with flow rate of argon (Ar) ranging from 40 sccm to 60 sccm, so as to evaluate sputtering characteristic of the targets, in which the evaluation items includes determining the number of undesired contaminant particles having a size of greater than 75 nm that are generated after the sputtering process is conducted for 5 minutes using a wafer particle counter (Manufacturer: KLA-Tencor Corporation; Model no.: Tencor Surfscan 6420), and observing degree of deformation using a coordinate measuring machine (CMM) during early and middle stages of the sputtering process as described follows. To be specific, each of the copper-based alloy sputtering targets was placed on a horizontal plane of the CMM to determine the warpage degree of a non-erosion region of the copper-based alloy sputtering target relative to the horizontal plane. When the copper-based alloy sputtering target has a warpage degree that is greater than 0.1 mm after the sputtering process is conducted for 72 hours, the copper-based alloy sputtering target is determined to have early stage deformation, and the thin film to be deposited thereon by the sputtering process may have a poor uniformity. On the other hand, when the copper-based alloy sputtering target has a warpage degree that is greater than 0.3 mm after the sputtering process is conducted for 240 hours, the copper-based alloy sputtering target is determined to have middle stage deformation and would easily crack, in addition to the poor uniformity of the thin film to be deposited thereon by the sputtering process. When the number of the undesired contaminant particles is greater than 5, the quality of the deposited thin film easily declines. The results regarding the occurrence of the early and/or middle stage deformation of each of the copper-based alloy sputtering targets, and the number of undesired contaminant particles are shown in Table 2 below.

TABLE 2

| Property evaluation | EX1 | EX2 | EX3 | CE1 | CE2 | CE3 |
|---|---|---|---|---|---|---|
| Metal element (Mn, | 0.3 | 0.8 | 2.0 | 0.3 | 0.8 | 2.0 |
| wt %) | | | | | | |
| Average KAM value | 0.96 | 1.32 | 1.82 | 0.65 | 0.47 | 3.17 |
| (°) | | | | | | |
| Average crystal | 17 | 26 | 20 | 18 | 40 | 23 |
| grain size (μm) | | | | | | |
| Average Vickers | 95 | 93 | 116 | 63 | 57 | 132 |
| hardness on the | | | | | | |
| sputtering surface | | | | | | |
| (Hv) | | | | | | |
| Early stage | No | No | No | Yes | Yes | No |
| deformation¹ | | | | | | |
| Middle stage | No | No | No | Yes | Yes | No |
| deformation² | | | | | | |
| Number of undesired | 2 | 4 | 4 | 5 | 10 | 12 |
| contaminant | | | | | | |
| particles (>75 nm) | | | | | | |

¹sputtering target is considered to have early stage deformation when warpage degree thereof is greater than 0.1 mm after being subjected to 72 hours of sputtering
²sputtering target is considered to have middle stage deformation when warpage degree thereof is greater than 0.3 mm after being subjected to 240 hours of sputtering

Referring to Table 2, in the copper-based alloy sputtering targets prepared in EX1 to EX3 and CE1 to CE3, the metal element, i.e., manganese (Mn), is present in an amount ranging from 0.3 wt % to 2 wt % based on a total weight of the copper-based alloy sputtering target. The copper-based alloy sputtering targets prepared by the methods of EX1 to EX3 have the average KAM value ranging from 0.96° to 1.82°, and the number of undesired contaminant particles generated during the sputtering process is at most 4, which demonstrates that in the methods of EX1 to EX3, the copper-based alloy ingots are capable of moderately releasing residual stress (strain energy) after the recrystallization heating treatment, such that after the cold forming process at a cold working rate of not greater than 50%, plastic deformation of the recrystallized product obtained from the recrystallization heating treatment would not have excessive strain energy accumulated therein, thereby resulting in a low number of undesired contaminant particles generated from the dust during the sputtering process. On the contrary, for the copper-based alloy sputtering target prepared by the method of CE3, the average KAM value is as high as 3.17°, and the number of undesired contaminant particles generated after the sputtering process is as high as 12, indicating that when the recrystallization heating treatment was conducted at a temperature of 700° C. within 0.5 hours, followed by cold forging conducted at a cold working rate of up to 70%, the residual stress would be difficult to be released, and the copper-based alloy sputtering target prepared by the method of CE3 which retains excessive strain energy would generate higher amount of undesired contaminant particles (i.e., exhibits lower sputtering resistance) than those of the copper-based alloy sputtering targets prepared by the methods of EX1 to EX3.

In addition, for the copper-based alloy sputtering targets prepared by the methods of EX1 to EX3, the average crystal grain size ranges from 17 μm to 26 μm, and the average value of Vickers hardness ranges from 93 Hv to 116 Hv, indicating that crystal grain refinement that is achieved twice in the method of this disclosure is beneficial not only for increasing the strength of the copper-based alloy sputtering targets prepared thereby, but also for improving the uniformity of a thin film to be formed by performing the sputtering process on the copper-based alloy sputtering targets. Moreover, the copper-based alloy sputtering targets prepared by the methods of EX1 to EX3 have the warpage degree that remains less than 0.1 mm after 72 hours of sputtering and less than 0.3 mm after 240 hours of sputtering, indicating absence of deformation during early and middle stages of the sputtering process (i.e., with enhanced sputtering resistance), which is capable of improving uniformity of a thin film to be formed, and reducing the possibility of cracking of the copper-based alloy sputtering targets.

In contrast, for the methods of CE1 and CE2, although the copper-based alloy sputtering targets prepared thereby respectively have the average KAM values of 0.65° and 0.47°, the average Vickers hardness thereof on the sputtering surface have been respectively reduced to 63 and 57, and both early stage deformation (the warpage degree greater than 0.1 mm) and middle stage deformation (the warpage degree greater than 0.3 mm) can be observed. These results confirm that the copper-based alloy sputtering target prepared by the method of CE1 (i.e., without performing the cold forming process) does not have sufficient hardness to resist the force of gravity, and may have deformation during early and middle stages of the sputtering process, which results in easy cracking of the copper-based alloy sputtering target, and a poor uniformity of the thin film to be formed. In addition, the copper-based alloy sputtering target prepared by the method of CE2, in which the recrystallization heating treatment is conducted at a temperature that is too high (750° C.), has excessively large crystal grain size, and a relatively low value of the average Vickers hardness on the sputtering surface, which leads to deformation during the early and middle stages of the sputtering process, and thus the copper-based alloy sputtering target may easily crack, and the thin film to be formed therefrom may have a poor uniformity.

In summary, by the method for making the copper-based alloy sputtering target of the present disclosure, which includes subjecting the copper-based alloy ingot to the hot forging process so as to achieve crystallization and grain refinement, and then performing the heating treatment and the cool rolling process so as to achieve strain hardening caused by plastic deformation, followed by performing the recrystallization heating treatment and the cold forming process in sequence, the crystal grains of the copper-based alloy sputtering target thus made can be refined twice, strain energy can be further released, and the hardness of the copper-based sputtering target can be further increased, so that the copper-based alloy sputtering target has an improved hardness on the sputtering surface, and excessive strain energy accumulated therein can be avoided.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A copper-based alloy sputtering target, comprising:
copper; and
a metal element selected from the group consisting of manganese, chromium, cobalt, aluminum, tin, titanium, and combinations thereof,
wherein based on a total weight of said copper-based alloy sputtering target, copper is present in an amount of not less than 98 wt %, and said metal element is present in an amount ranging from 0.3 wt % to 2.0 wt %,
wherein said copper-based alloy sputtering target has an average value of Kernel Average Misorientation (KAM) of not greater than 2°, as determined by Electron Backscatter Diffraction (EBSD); and
wherein said copper-based alloy sputtering target has an average value of Vickers hardness on a sputtering surface that ranges from 90 Hv to 120 Hv.

2. The copper-based alloy sputtering target as claimed in claim 1, wherein said metal element is manganese.

3. The copper-based alloy sputtering target as claimed in claim 1, which has an average crystal grain size of not greater than 30 μm as determined according to ASTM E112.

4. The copper-based alloy sputtering target as claimed in claim 1, wherein the average value of KAM ranges from 0.9° to 1.9°, as determined by EBSD.

5. A method for making a copper-based alloy sputtering target as claimed in claim 1, comprising the steps of:
(a) melting copper and a metal element selected from the group consisting of manganese, chromium, cobalt, aluminum, tin, titanium, and combinations thereof to form a molten copper-based alloy in which based on a total weight of the molten copper-based alloy, copper is present in an amount of not less than 98 wt %, and the metal element is present in an amount ranging from 0.3 wt % to 2.0 wt %;
(b) casting the molten copper-based alloy in a mold to form a copper-based alloy ingot;
(c) subjecting the copper-based alloy ingot to a hot forging process at a forging ratio of greater than 40% under a temperature ranging from 600° C. to 1000° C.;
(d) subjecting the forged product obtained in step (c) to a heating treatment at a temperature ranging from 400° C. to 700° C. for a time period ranging from 1 hour to 3 hours;
(e) subjecting the heat-treated product obtained in step (d) to a cold rolling process at a cold rolling rate ranging from 40% to 75%;
(f) subjecting the cold-rolled product obtained in step (e) to a recrystallization heating treatment at a temperature ranging from 450° C. to 700° C. for a time period ranging from 1 hour to 3 hours; and
(g) subjecting the recrystallized product obtained in step (f) to a cold forming process at a cold working rate of not greater than 50% under a room temperature, so as to obtain the copper-based alloy sputtering target.

6. The method as claimed in claim 5, wherein in step (c), the forging ratio of the hot forging process ranges from 40% to 50%.

7. The method as claimed in claim 5, wherein in step (d), the temperature of the heating treatment ranges from 400° C. to 550° C.

8. The method as claimed in claim 5, wherein in step (e), the cold rolling rate of the cold rolling process ranges from 65% to 75%.

9. The method as claimed in claim 5, wherein in step (g), the cold forming process is selected from the group consisting of cold rolling, cold forging, cold extrusion, cold drawing, and combinations thereof.
